(19) United States
(12) Patent Application Publication
(10) Pub. No.: US 2025/0087622 A1
(43) Pub. Date: Mar. 13, 2025

(54) SEMICONDUCTOR DEVICE

(71) Applicant: Renesas Electronics Corporation, Tokyo (JP)

(72) Inventor: Kazuaki OSAWA, Tokyo (JP)

(21) Appl. No.: 18/773,957

(22) Filed: Jul. 16, 2024

(30) Foreign Application Priority Data
Sep. 13, 2023 (JP) 2023-148527

(51) Int. Cl. H01L 23/00

(52) U.S. Cl. CPC H01L 24/48; H01L 24/45; H01L 24/49; H01L 2224/45014; H01L 2224/45124; H01L 2224/48245; H01L 2224/48465; H01L 2224/4903; H01L 2924/12; H01L 2924/13091

(57) ABSTRACT

A semiconductor device according to the embodiment includes a semiconductor chip having a first MOSFET formed in a first region of a semiconductor substrate, a detection element formed in a second region within the first region, a source electrode formed above the first region and connected to a source of the first MOSFET, and a source electrode material arranged to cover the detection element and stitch-bonded to the source electrode.

### CROSS-REFERENCE TO RELATED APPLICATIONS

The disclosure of Japanese Patent Application No. 2023-148527 filed on Sep. 13, 2023, including the specification, drawings and abstract is incorporated herein by reference in its entirety.

### BACKGROUND

The present invention relates to a semiconductor device.

It is known that there are detection elements that protect a power MOSFET when an abnormal current (overcurrent) is passed through the power MOSFET. Examples of such detection elements include a current detection element that includes a sense MOSFET, and a temperature detection element that includes a diode.

Patent Document 1 discloses a technique related to the arrangement of detection elements in a power MOSFET. In Patent Document 1, a metal plate overlapping with a source electrode includes a source connection part connected to the source electrode and an extension part extending toward a source terminal arranged on the short side from the source connection part. The extension part is arranged to overlap with the detection element in plan view.

### PRIOR ART DOCUMENT

### Patent Document

[Patent Document 1] Japanese Unexamined Publication Laid-Open No. 2020-145219

### SUMMARY

A power MOSFET is composed of multiple unit transistor cells arranged in a matrix, and a source electrode formed on the main surface of a semiconductor substrate and a drain electrode formed on the back surface are common to the multiple unit transistor cells. When an abnormal current (overcurrent) flows through the power MOSFET, it is known that the central part of the semiconductor chip where the power MOSFET is formed becomes hotter than the edge part, that is, a temperature difference occurs between the central part and the edge part of the semiconductor chip.

In Patent Document 1, the detection element is arranged at the edge part of the semiconductor chip so as to be overlapped by the extension part extending from the source electrode to the source terminal. When the detection element is arranged at the edge part in this way, it takes several hundred us for the detection element to react to the heat caused by the overcurrent and to perform a cutoff operation due to the above-mentioned temperature difference. In a semiconductor device equipped with a power MOSFET, it is desired to improve the responsiveness of the detection element.

Other problems and novel features will become apparent from the description of this specification and the accompanying drawings.

A semiconductor device according to the present embodiment includes a semiconductor chip that includes a first MOSFET formed in a first region of a semiconductor substrate, a detection element formed in a second region within the first region, and a source electrode formed above the first region and electrically connected to the source of the first MOSFET, and a source electrode material that is arranged to cover the detection element and is stitch-bonded to the source electrode.

The present disclosure can improve the responsiveness of the detection element of a semiconductor device equipped with a power MOSFET.

### BRIEF DESCRIPTION OF THE DRAWINGS

FIG. 1 is a plan perspective view showing a configuration example of a semiconductor device according to a first embodiment.

FIG. 2 is a sectional view of a main part of FIG. 1.

FIG. 3 is a photograph showing a section along the line II- in FIG. 1.

FIG. 4 is a photograph showing a section along the line II-II in FIG. 1.

FIG. 5 is a plan perspective view showing a configuration example of a semiconductor device according to a second embodiment.

FIG. 6 is a diagram explaining the temperature difference-Ids (Vds=constant) characteristics of the semiconductor device in

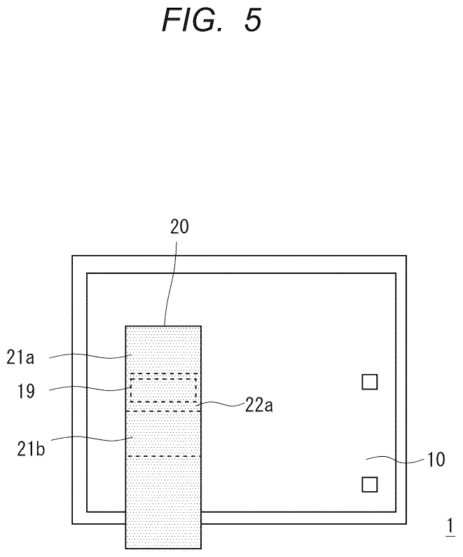

FIG. 5.

FIG. 7 is a circuit diagram showing a configuration example of a semiconductor device in which a high-side configuration is adopted.

FIG. 8 is a circuit diagram showing a configuration example of a semiconductor device in which a low-side configuration is adopted.

FIG. 9 is a plan perspective view of a comparative example of a semiconductor device.

FIG. 10 is a sectional view along the line X-X in FIG. 9.

### DETAILED DESCRIPTION

Hereinafter, embodiments of the present disclosure will be described with reference to the drawings. Note that the drawings are simplified, and the technical scope of the present disclosure should not be narrowly interpreted based on the description of these drawings. Also, in each drawing, the same elements are given the same reference numerals, and redundant descriptions are omitted. Note that, for convenience of explanation, each drawing is not drawn to actual scale.

In the following embodiments, for convenience, when necessary, the explanation is divided into multiple sections or embodiments. However, unless specifically stated, they are not unrelated to each other, and one is related to the other as a part or all of the variations, applications, detailed explanations, supplementary explanations, etc.

Also, in the following embodiments, when referring to the number of elements, etc. (including the number, numerical value, quantity, range, etc.), unless specifically stated and it is fundamentally clear that it is limited to a specific number, it is not limited to that specific number, and it may be more or less than that specific number.

Furthermore, in the following embodiments, the components (including operation steps, etc.) are not necessarily essential, except when specifically stated and when it is fundamentally clear that they are essential. Similarly, in the following embodiments, when referring to the shape, positional relationship, etc. of the components, etc., unless specifically stated and when it is fundamentally clear that it is not so, it includes those that are substantially similar or similar to that shape, etc. This applies to the above-mentioned numbers, etc. (including the number, numerical value, quantity, range, etc.).

In this disclosure, the field effect transistor is described as MOSFET (Metal Oxide Semiconductor Field Effect Transistor), or simply MOS, but it includes not only when an oxide film is used as a gate insulating film, but also when an insulating film other than the oxide film is used as the gate insulating film.

The embodiments relate to semiconductor devices for power used to drive loads such as motors, heaters, lamps, etc. mounted on automobiles, and semiconductor devices applied to industrial programmable logic controllers (Programmable Logic Controller). Such semiconductor devices use power MOSFETs and IGBTs (Insulated Gate Bipolar Transistor).

The semiconductor device of the embodiment is applied to a drive circuit of a high-side configuration or a low-side configuration, for example. FIG. 7 is a circuit diagram showing a configuration example of a semiconductor device 1 in which the high-side configuration is adopted. As shown in FIG. 7, the semiconductor device 1 includes an output transistor 3 and a body diode 4. The body diode 4 is provided between the source and drain of the output transistor 3. Between the power supply terminal VBAT where the power supply voltage is supplied and the ground terminal GND where the ground voltage is supplied, the output transistor 3 and the load 2 are connected in series in this order. The output transistor 3 is provided between the power supply terminal VBAT and the load 2. That is, the output transistor 3 is used as a high-side switch.

FIG. 8 is a circuit diagram showing a configuration example of a semiconductor device 1 in which a low-side configuration is adopted. As shown in FIG. 8, the semiconductor device 1 includes an output transistor 3 and a body diode 4. The body diode 4 is provided between the source and drain of the output transistor 3. Between the power supply terminal VBAT and the ground terminal GND, the load 2 and the output transistor 3 are connected in series in this order. The output transistor 3 is provided between the load 2 and the ground terminal GND. That is, the output transistor 3 is used as a low-side switch.

These semiconductor devices are provided with a detection element to protect the power MOSFET when an abnormal current (overcurrent) is passed through the power MOSFET. First, a comparative example of a semiconductor device having a power MOSFET provided with a temperature detection element as the detection element will be described.

FIG. 9 is a plan view of the semiconductor device of the comparative example. FIG. 10 is a cross-sectional view taken along line X-X in FIG. 9. As shown in FIGS. 9 and 10, the semiconductor device 1 of the comparative example mainly includes a semiconductor chip 10, a temperature detection element 11, and a metal plate 12. The semiconductor chip 10 is mounted on a main surface of a die pad 13 via an adhesive layer 14.

In the center of the main surface of the semiconductor chip 10, a main MOS region (not shown) is provided, and at the edge, a temperature detection diode region serving as the temperature detection element 11 is provided.

A metal plate 12 is connected via an adhesive layer 15 to a source pad (first source electrode, not shown) provided on the main MOS region. That is, in the example shown in FIG. 9, the clip-shaped metal plate 12 serves as a source electrode material connected to the source electrode of the power MOSFET. The adhesive layers 14, 15 may be, for example, solder or silver paste. In this way, when using the metal plate 12, an adhesive process is required to adhere the metal plate 12 and the semiconductor chip 10 with the adhesive layer 15.

The metal plate 12 has a source connection part 12a and an extension part 12b, the extension part includes an overhang part and a lead connection part. The metal plate 12 is connected to the source pad at the source connection part and to the source terminal at the lead connection part. The overhang part between the source connection part and the lead connection part is positioned on the temperature detection element 11 and covers the metal plate 12.

The semiconductor chip 10, the metal plate 12, and the die pad 13 are covered with a sealing body 18. The sealing body 18 is composed of an insulating resin body such as epoxy resin. The sealing body 18 is filled between the temperature detection element 11 on the semiconductor chip 10 and the overhang part of the metal plate 12, and they are electrically separated by the insulating resin.

As shown in FIGS. 9 and 10, the temperature detection element 11 is provided at the edge of the semiconductor chip 10. Since a temperature difference occurs between point A (the center of the semiconductor chip 10) and point B (the edge of the semiconductor chip 10) shown in FIG. 9, the detection element needs several hundred us to respond to heat caused by overcurrent and to perform a cutoff operation. In a semiconductor device equipped with a power MOSFET, it is desirable to improve the responsiveness of the detection element. Also, when placing the temperature detection element 11 in the center of the semiconductor chip 10, it is necessary to provide an insulator between the metal plate 12 and the temperature detection element 11 to prevent short-circuiting, which increases the manufacturing process. Therefore, the present inventors have devised the following configuration to solve these problems.

### First Embodiment

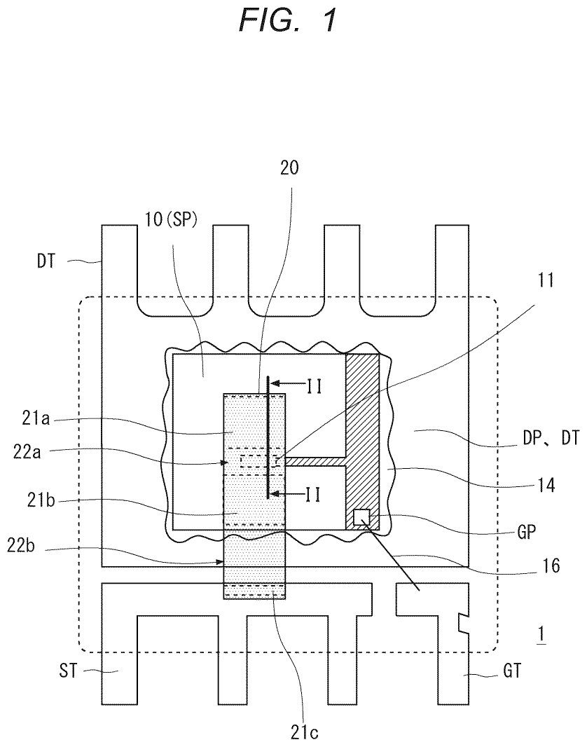

FIG. 1 is a plan perspective view showing a configuration example of a semiconductor device 1 according to the first embodiment. As shown in FIG. 1, the semiconductor device 1 is a semiconductor package of the SOP (Small Outline package) type. As shown in FIG. 1, the semiconductor device 1 mainly includes a semiconductor chip 10, a temperature detection element 11, and a ribbon wire 20.

The semiconductor chip 10 includes a main MOS region where a power MOSFET is formed, and a temperature detection diode region where the temperature detection element 11 is formed. The power MOSFET is a transistor for switching. As explained in FIGS. 7 and 8, when an on-voltage is applied to a gate of the power MOSFET and the power MOSFET is turned on, a current flows through the power MOSFET and the load 2 connected in series between the power supply terminal VBAT and the ground potential GND. On the other hand, if an off-voltage is applied to the gate of the power MOSFET and the power MOSFET is turned off, it is possible to prevent a current from flowing through the power MOSFET and the load 2 connected in series.

Also, the semiconductor chip 10 includes a source pad SP and a gate pad GP. The semiconductor device 1 is provided with a plurality of terminals serving as external terminals. The plurality of terminals is electrically connected to the semiconductor chip 10. The plurality of terminals include a gate terminal GT, a source terminal ST, and a drain terminal DT. The plurality of terminals is composed of leads formed by processing a copper plate or a 42 alloy plate with a film thickness of about 250 μm into a desired shape. The source terminal ST is a terminal for supplying current to the load 2, as shown in FIGS. 7 and 8.

In the example shown in FIG. 1, multiple drain terminals DT connected to the drain of the power MOSFET are arranged on the upper edge of the semiconductor device 1.

Multiple source terminals ST connected to the source of the power MOSFET are arranged on the left side of the lower edge of the semiconductor device 1, which faces the upper edge where the drain terminals DT are provided.

The gate terminal GT connected to the gate of the power MOSFET is arranged on the right side of the lower edge where the source terminals ST are formed. The die pad DP and multiple drain terminals DT are integrally formed. The semiconductor chip 10 is mounted on the die pad DP via an adhesive layer 14. The gate terminal GT and the gate pad GP are connected by a wire 16. The wire 16 is, for example, made of a copper wire or a gold wire with a diameter of 30 to 50 μm. In addition, instead of the wire 16, a metal ribbon wire with a wider width than the wire 16 can also be used. The gate terminal GT is electrically connected to a drive circuit (not shown). The drive circuit controls the potential of the gate of the power MOSFET and controls the operation of the power MOSFET.

A ribbon wire 20 is used as the source electrode material. The ribbon wire 20 is a band-shaped electrode material made of a flexible aluminum foil with a thickness of about 150 to 250 μm. The ribbon wire 20 is located on the source pad SP of the semiconductor chip 10. The ribbon wire 20 electrically connects the source pad SP and the source terminal ST.

The ribbon wire 20 is connected to the source terminal ST and the source pad SP by wire bonding. In wire bonding, the tip of the ribbon wire 20 held by a bonding tool (not shown) is connected to the center part (first bonding point) of the source pad SP of the semiconductor device 1. Then, the ribbon wire 20 is pulled around, and its intermediate part is connected to the end part (second bonding point) of the source pad SP. Furthermore, the ribbon wire 20 is pulled around, and its intermediate part is connected to the source terminal ST (third bonding point). Near the connection part of the source terminal ST, the ribbon wire 20 is cut off, thereby ending one round of wire bonding.

The connection between the ribbon wire 20 and the source pad SP or source terminal ST is made by stitch bonding. Specifically, the ribbon wire 20 is pressed against the source pad SP while applying ultrasonic vibration. As a result, the ribbon wire 20 is bonded to the source pad SP, forming a stitch joint. Thus, the embodiment performs the bonding of the ribbon wire 20 and the source pad SP and source terminal ST by an ultrasonic bonding method, and a bonding process using solder or the like is unnecessary. The stitch joint formed at the first bonding point is referred to as the first stitch joint 21a, the stitch joint formed at the second bonding point is referred to as the second stitch joint 21b, and the stitch joint formed at the third bonding point is referred to as the third stitch joint 21c.

The ribbon wire 20 between the first stitch joint 21a and the second stitch joint 21b is not bonded to the source pad SP, and there is a space between the ribbon wire 20 and the source pad SP. The ribbon wire 20 on this space is referred to as the first overhang portion 22a. Also, the ribbon wire 20 between the second stitch joint 21b and the third stitch joint 21c is not bonded to the die pad DP or the like, and there is a space between the ribbon wire 20 and the die pad DP or the like. The ribbon wire 20 on this space is referred to as the second overhang portion 22b. In other words, the ribbon wire 20 includes the first stitch joint 21a, the second stitch joint 21b, the third stitch joint 21c, the first overhang portion 22a, and the second overhang portion 22b.

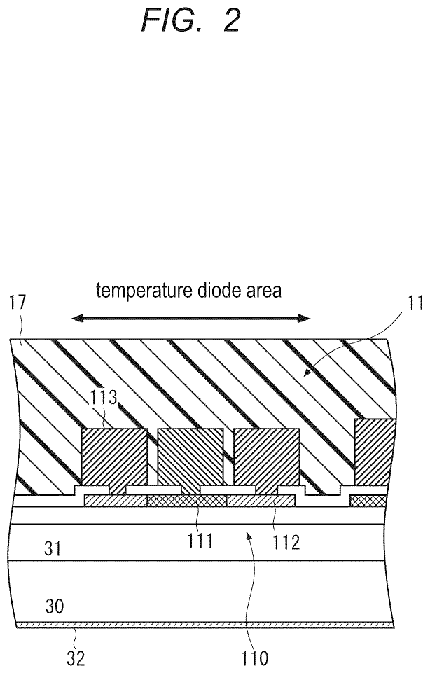

An area facing the first overhang portion 22a of the semiconductor chip 10 is a temperature diode area where a temperature detection element 11 is provided. The temperature detection element 11 is a temperature diode in which multiple diodes are connected in series. Here, referring to FIG. 2, the temperature detection element 11 will be described. FIG. 2 is a cross-sectional view of the essential part where the temperature detection element 11 of FIG. 1 is formed.

In the example shown in FIG. 2, an epitaxial wafer is used as the semiconductor substrate. The semiconductor substrate is composed of a substrate body 30 made of, for example, n+ type single crystal silicon into which n type impurities such as arsenic (As) have been introduced, and an epitaxial semiconductor layer 31 made of, for example, n− type single crystal silicon formed on the main surface of the substrate body 30. The semiconductor substrate SB may be n type single crystal silicon into which n type impurities such as arsenic (As) have been introduced.

The power MOSFET (not shown) and the temperature detection element 11 are formed on the semiconductor substrate. In the center of the main surface of the semiconductor substrate, a main MOS area, which is the formation area of the power MOSFET, is arranged. Also, in the main MOS area, a temperature diode area, which is the formation area of the temperature detection element 11, is arranged at a position facing the first overhang portion 22a.

Although not shown here, multiple unit transistor cells constituting the power MOSFET are formed on the semiconductor substrate in the main MOS area. The power MOSFET is formed by connecting multiple unit transistor cells provided in the main MOS area in parallel. The semiconductor substrate has the function of a drain area of the unit transistor cell in the main MOS area. A backside electrode 32 for the drain is formed on the backside (i.e., the backside of the semiconductor chip 10) of the substrate body 30. The backside electrode 32 is formed by stacking a titanium (Ti) layer, a nickel (Ni) layer, and a gold (Au) layer from the backside of the substrate body 30. The backside electrode 32 is connected to the die pad DP and the drain terminal DT of FIG. 1.

As shown in FIG. 2, in the temperature diode area, a temperature detection element 11 in which multiple diodes 110 are connected in series is formed. The diode 110 is composed of, for example, a polysilicon layer having a PN junction.

In the polysilicon layer, an anode 111 containing p type impurities and a cathode 112 containing n type impurities are formed. Multiple diodes 110 are connected by diode connection wiring 113.

The multiple diodes 110 connected in series are connected to an anode electrode and a cathode electrode, respectively, via an anode wiring and a cathode wiring (not shown). The multiple diodes 110 and the diode connection wiring 113 are covered by a protective film 17 made of polyimide resin. In the protective film 17, openings are provided that expose part of the anode electrode and the cathode electrode, and an anode pad and a cathode pad are formed there.

In this way, in the first embodiment, the temperature detection element 11 is formed in the main MOS area where the power MOSFET is formed in the center of the semiconductor chip 10. The temperature detection element 11 is covered by the ribbon wire 20 that is stitch bonded. The ribbon wire 20 is stitch bonded at least at a first stitch joint 21a and a second stitch joint 21b. The temperature detection element 11 is arranged under the first overhang 22a between the first stitch joint 21a and the second stitch joint 21b. In other words, the temperature detection element 11 is inserted into the space between the first overhang 22a between the first stitch joint 21a and the second stitch joint 21b and the source pad SP.

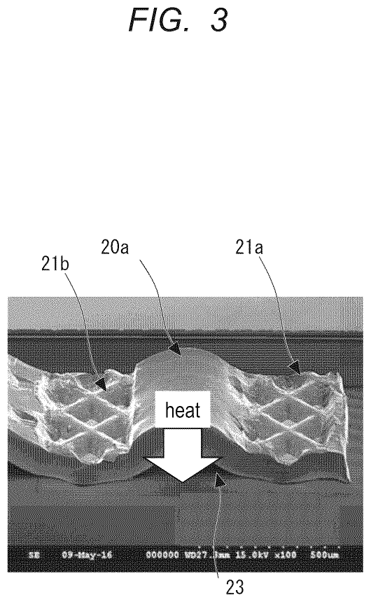

FIG. 3 is a photograph showing a cross section taken along line II-II in FIG. 1. FIG. 3 is a photograph taken from the right side in FIG. 1 of the cross section of the semiconductor device 1 along the line II-II. As shown in FIG. 3, there is a space 23 between the first overhang 22a and the semiconductor chip 10.

As shown in FIG. 3, the heat generated by the semiconductor chip 10 is conducted directly to the temperature detection element 11 and also conducted from the ribbon wire 20. This allows the heat generated by the semiconductor chip 10 to be transmitted to the temperature detection element 11 more quickly, improving the thermal response. In this way, by improving the thermal response, it is possible to quickly enter the cutoff operation when an overcurrent state occurs due to a load short circuit, etc., protecting the element and improving the destruction tolerance of the product.

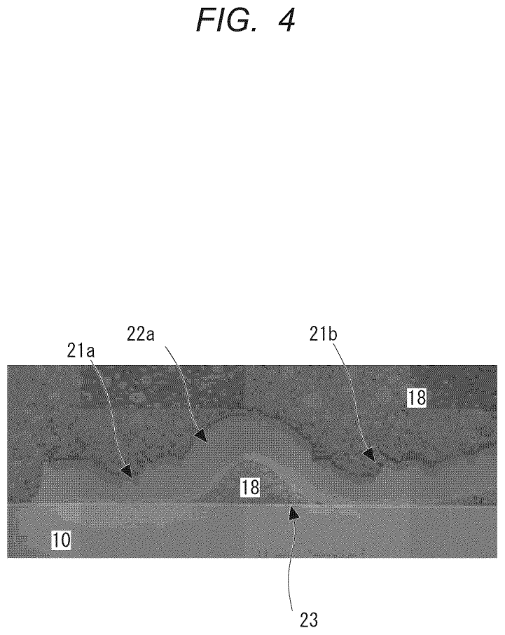

Although not shown in FIG. 1, the semiconductor device 1 further includes a sealing body that seals the semiconductor chip 10, the die pad DP, multiple terminals, the ribbon wire 20, and the wire 16. The sealing body is composed of an insulating resin body such as epoxy resin. FIG. 4 is a photograph showing a cross section taken along line II-II in FIG. 1. FIG. 4 is a photograph taken from the left side in FIG. 1 of the cross section of the semiconductor device 1 along the line II-II. As shown in FIG. 4, the space 23 between the first overhang 22a and the semiconductor chip 10 is filled with the sealing body 18. This electrically isolates the two by the sealing body 18.

In order to supply heat from the first overhang 22a to the temperature detection element 11, in plan view, it is sufficient for the first overhang 22a to overlap at least a part of the temperature detection element 11. It is preferable that the first overhang 22a overlaps the entire area of the temperature detection element 11.

### Second Embodiment

FIG. 5 is a plan perspective view showing a configuration example of the semiconductor device 1 according to the second embodiment. In FIG. 2, the illustration of the source terminal ST, the gate terminal GT, the drain terminal DT, etc. is omitted. In FIG. 5, the same components as in FIG. 1 are denoted by the same reference numerals, and the description is appropriately omitted.

In the second embodiment, a sense MOS 19 is formed instead of the temperature detection element 11. That is, the semiconductor chip 10 includes a main MOS area where a power MOSFET is formed and a sense MOS area where a sense MOSFET, which is a current detection element for detecting the current flowing through the power MOSFET, is formed. The Sense MOS 19 is formed within the main MOS region where the power MOSFET is formed in the central part of the semiconductor chip 10.

In the sense MOS region, multiple unit transistor cells that constitute the sense MOSFET, which is a current detection element, are formed on the semiconductor substrate. The sense MOSFET is formed by connecting these multiple unit transistor cells provided in the sense MOS region in parallel.

Each unit transistor cell formed in the main MOS region and each unit transistor cell formed in the sense MOS region essentially have the same structure (configuration). However, the main MOS region and the sense MOS region differ in area, with the main MOS region having a larger area than the sense MOS region.

Therefore, the number of unit transistor cell connections differs between the power MOSFET and the sense MOSFET. The number of parallel-connected unit transistor cells constituting the sense MOSFET is less than the number of parallel-connected unit transistor cells constituting the power MOSFET. Therefore, if the source potentials of the sense MOSFET and the power MOSFET are the same, a smaller current flows through the sense MOSFET than the current flowing through the power MOSFET.

Each unit transistor cell in the main MOS region and the sense MOS region is formed, for example, by an n-channel MOSFET with a trench gate structure. In the second embodiment, the on/off of the power MOSFET and the sense MOSFET is controlled by supplying a gate voltage to the gate terminal GT.

The sense MOSFET is a field effect transistor for detecting the current flowing through the power MOSFET. The current flowing through the power MOSFET can be indirectly detected by the sense MOSFET. The sense MOSFET is formed within the semiconductor chip 10 to form a current mirror circuit with the power MOSFET.

The sense MOSFET, for example, has a size of 1/n (where n is any integer) of the power MOSFET. This size ratio can be changed as needed. If the source voltage of the sense MOSFET and the source voltage of the power MOSFET are equal, due to the above-mentioned current mirror configuration, a current of 1/n of the current flowing through the power MOSFET flows through the sense MOSFET. In other words, if the size ratio of the power MOSFET and the sense MOSFET is known, the current flowing through the power MOSFET can be determined by monitoring the current flowing through the sense MOSFET.

The drain and gate of the sense MOSFET are common with the power MOSFET. That is, the drains of the sense MOSFET and the power MOSFET are electrically connected. This common drain is connected to the drain terminal DT, and the same potential is supplied to the drain of the sense MOSFET and the drain of the power MOSFET. Also, the gates of the sense MOSFET and the power MOSFET are electrically connected and made common. This common gate is connected to the gate terminal GT, and the same gate voltage is input to the gate of the sense MOSFET and the gate of the power MOSFET.

On the other hand, the source of the sense MOSFET is not common with the source of the power MOSFET. The source pad SP (first source electrode) of the power MOSFET is connected to the source terminal ST, and the load 2 is connected to the source terminal ST. In contrast, the source electrode (second source electrode) of the sense MOSFET is connected to a source terminal different from the source terminal ST.

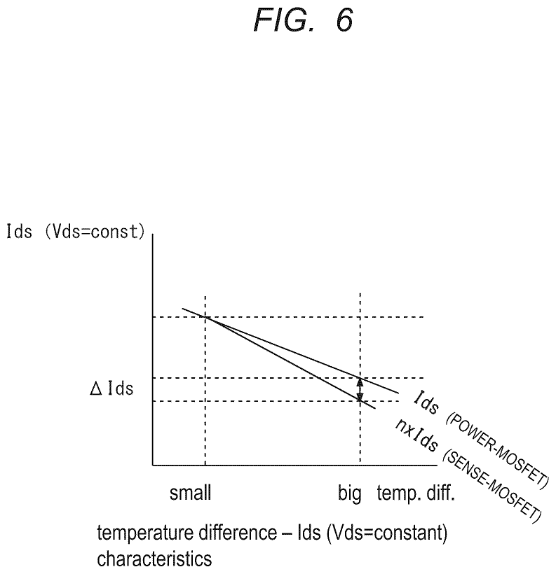

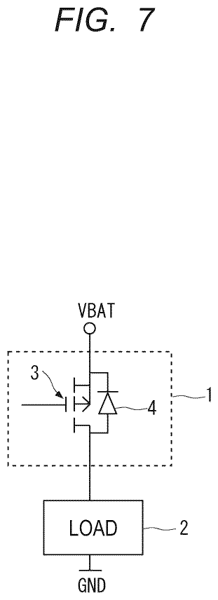

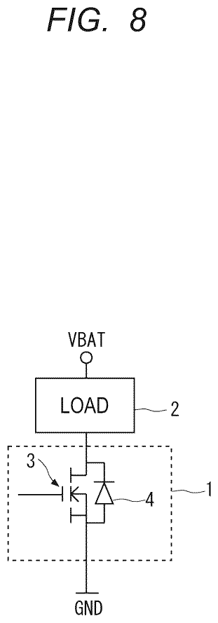

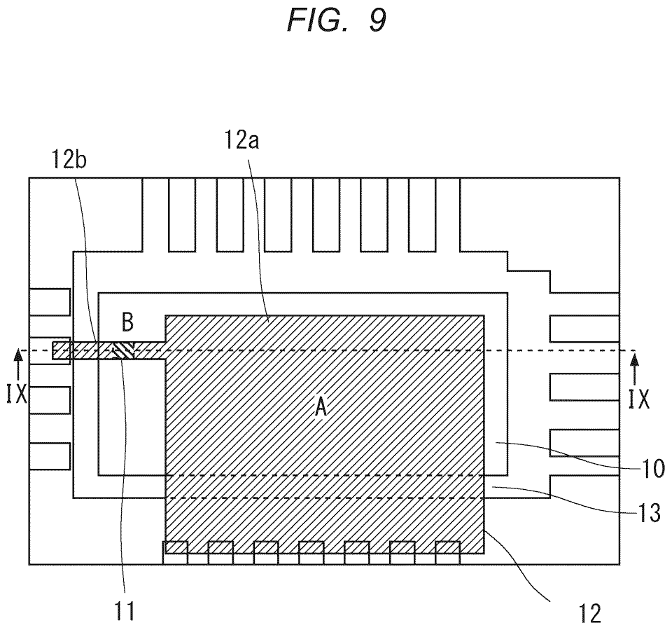

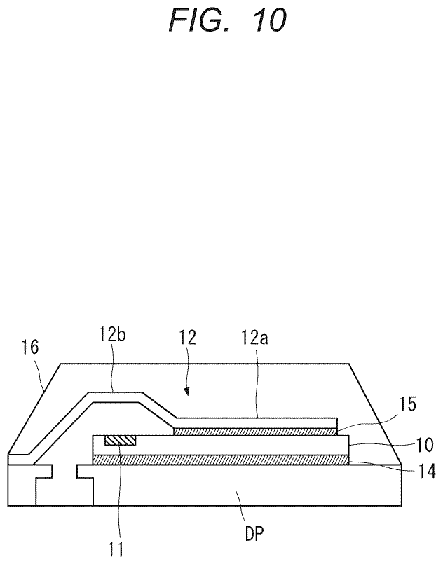

FIG. 6 is a diagram explaining the temperature difference-Ids (Vds=constant) characteristics of the semiconductor device in FIG. 5. In FIG. 6, the horizontal axis represents the temperature difference between the power MOSFET and the sense MOSFET, and the vertical axis represents Ids. Ids (power MOSFET) represents the current flowing through the power MOSFET. Ids (sense MOSFET) represents the current flowing through the sense MOSFET. Vds represents the drain-source potential of the sense MOSFET and the power MOSFET.

Theoretically, the current Ids (power MOSFET) flowing through the power MOSFET is equal to n times the current Ids (sense MOSFET) flowing through the sense MOSFET.

For example, as shown in FIGS. 9 and 10, when a sense MOS 19 is provided on the edge of a semiconductor chip 10 where a temperature detection element 11 is arranged, the temperature of the sense MOSFET becomes lower than that of the power MOSFET. As shown in FIG. 6, because the temperature difference between the power MOSFET and the sense MOSFET becomes large, ΔIds, which is the difference between Ids (power MOSFET) and n×Ids (sense MOSFET), becomes large, making it impossible to accurately detect current (refer to the large temperature difference in FIG. 6).

In contrast, in the second embodiment, the sense MOS 19 is covered by the ribbon wire 20 that is stitch bonded. The ribbon wire 20 is stitch bonded at least at a first stitch joint 21a and a second stitch joint 21b. The sense MOS 19 is arranged under the first overhang 22a between the first stitch joint 21a and the second stitch joint 21b. In other words, the sense MOS 19 is inserted into the space between the first overhang 22a between the first stitch joint 21a and the second stitch joint 21b and the source pad SP.

With the above configuration, the heat generated in the semiconductor chip 10 is directly conducted to the sense MOS 19 and also conducted from the ribbon wire 20. This can reduce the temperature difference between the sense MOSFET and the power MOSFET, decrease ΔIds, and enable accurate current detection (refer to the small temperature difference in FIG. 6).

The invention made by the present inventor has been specifically described based on the embodiments, but the present invention is not limited to the embodiments described above, and various changes can be made within the scope not departing from the gist of the invention. For example, instead of the above-mentioned SOP type package, it is also possible to use an LGA (Land Grid Array) package in which a semiconductor chip is mounted on the main surface side of a glass epoxy substrate or a build-up substrate, and lands are arranged in a matrix on the back surface side of the substrate.

What is claimed is:

1. A semiconductor device comprising:
a semiconductor chip including a first MOSFET formed in a first region of a semiconductor substrate, a detection element formed in a second region within the first region, and a source electrode formed above the first region and connected to a source of the first MOSFET; and
a source electrode material arranged to cover the detection element and stitch-bonded to the source electrode.

2. The semiconductor device according to claim 1, wherein the source electrode material is stitch-bonded at least at a first joint and a second joint, and the detection element is arranged below the source electrode material between the first junction and the second junction.

3. The semiconductor device according to claim 1, wherein the source electrode material is a ribbon wire made of aluminum.

4. The semiconductor device according to claim 1, wherein the detection element is a temperature detection element, and the temperature detection element includes a plurality of diodes connected in series.

5. The semiconductor device according to claim 1, wherein the detection element is a current detection element, and the current detection element includes a second MOSFET and a second source electrode connected to a source of the second MOSFET.
